(19) United States
(12) Patent Application Publication
(10) Pub. No.: US 2016/0181148 A1
(43) Pub. Date: Jun. 23, 2016

(54) SEMICONDUCTOR DEVICE AND METHOD OF MANUFACTURING THE SAME

(71) Applicant: Kabushiki Kaisha Toshiba, Minato-ku (JP)

(72) Inventor: Makoto SAKUMA, Kuwana (JP)

(73) Assignee: Kabushiki Kaisha Toshiba, Minato-ku (JP)

(21) Appl. No.: 14/641,935

(22) Filed: Mar. 9, 2015

Related U.S. Application Data
(60) Provisional application No. 62/094,644, filed on Dec. 19, 2014.

(51) Int. Cl. H01L 21/768; H01L 23/528; H01L 27/115

(52) U.S. Cl. CPC H01L 21/76811; H01L 27/11529; H01L 23/5283; H01L 21/76816

(57) ABSTRACT

In one embodiment, a semiconductor device includes a substrate, first and second interconnects provided on the substrate to be apart from each other, and third and fourth interconnects provided on the substrate to be apart from each other. The device further includes a first pad portion connected with the first or third interconnect, and a second pad portion connected with the second or fourth interconnect, and provided to be apart from the first pad portion. The device further includes one or more fifth interconnects including an interconnect provided between the first interconnect and the second interconnect, and provided between at least one of the first and second pad portions and the first interconnect, and one or more sixth interconnects including an interconnect provided between the third interconnect and the fourth interconnect, and provided between at least one of the first and second pad portions and the third interconnect.

### CROSS REFERENCE TO RELATED APPLICATION

This application is based upon and claims the benefit of priority from the prior U.S. Provisional Patent Application No. 62/094,644 filed on Dec. 19, 2014, the entire contents of which are incorporated herein by reference.

### FIELD

Embodiments described herein relate to a semiconductor device and a method of manufacturing the same.

### BACKGROUND

In recent years, fine patterns of a semiconductor device are often formed by sidewall transfer process. For example, word lines of a semiconductor storage device such as a NAND memory are formed by the sidewall transfer process for downscaling purposes in many cases. However, when the word lines are formed by the sidewall transfer process, the reduction of the line width and the space width of the word lines makes it difficult to form pad portions (hook-up portions), which are used to dispose contact plugs on the word lines. The reason is that the reduction of these widths makes it difficult, when lithography for processing the pad portions is performed, to perform the alignment in lithography for dividing the pad portions and cutting the word lines from the pad portions. Therefore, a method that can process the pad portions simply and accurately is demanded.

### BRIEF DESCRIPTION OF THE DRAWINGS

FIGS. 1A to 6B are plan views and cross-sectional views showing a method of manufacturing a semiconductor device of a first embodiment;

FIGS. 7 and 8 are plan views showing the method of manufacturing the semiconductor device of the first embodiment;

FIG. 9 is a graph showing a relation of an initial space width between patterns of an upper layer and a final space width between patterns of a lower layer, when the patterns of the upper layer are transferred to the lower layer;

FIGS. 10A to 10C are plan views showing methods of manufacturing semiconductor devices of modifications of the first embodiment;

FIGS. 11 to 14 are plan views showing a method of manufacturing a semiconductor device of a second embodiment;

FIGS. 15A to 20B are plan views and cross-sectional views showing a method of manufacturing a semiconductor device of a third embodiment; and

FIG. 21 is a plan view showing the method of manufacturing the semiconductor device of the third embodiment.

### DETAILED DESCRIPTION

Embodiments will now be explained with reference to the accompanying drawings.

In one embodiment, a semiconductor device includes a substrate, first and second interconnects provided on the substrate so as to be apart from each other, and third and fourth interconnects provided on the substrate so as to be apart from each other. The device further includes a first pad portion connected with the first or third interconnect, and a second pad portion connected with the second or fourth interconnect, and provided so as to be apart from the first pad portion. The device further includes one or more fifth interconnects including an interconnect provided between the first interconnect and the second interconnect, and provided between at least one of the first and second pad portions and the first interconnect, and one or more sixth interconnects including an interconnect provided between the third interconnect and the fourth interconnect, and provided between at least one of the first and second pad portions and the third interconnect.

### First Embodiment

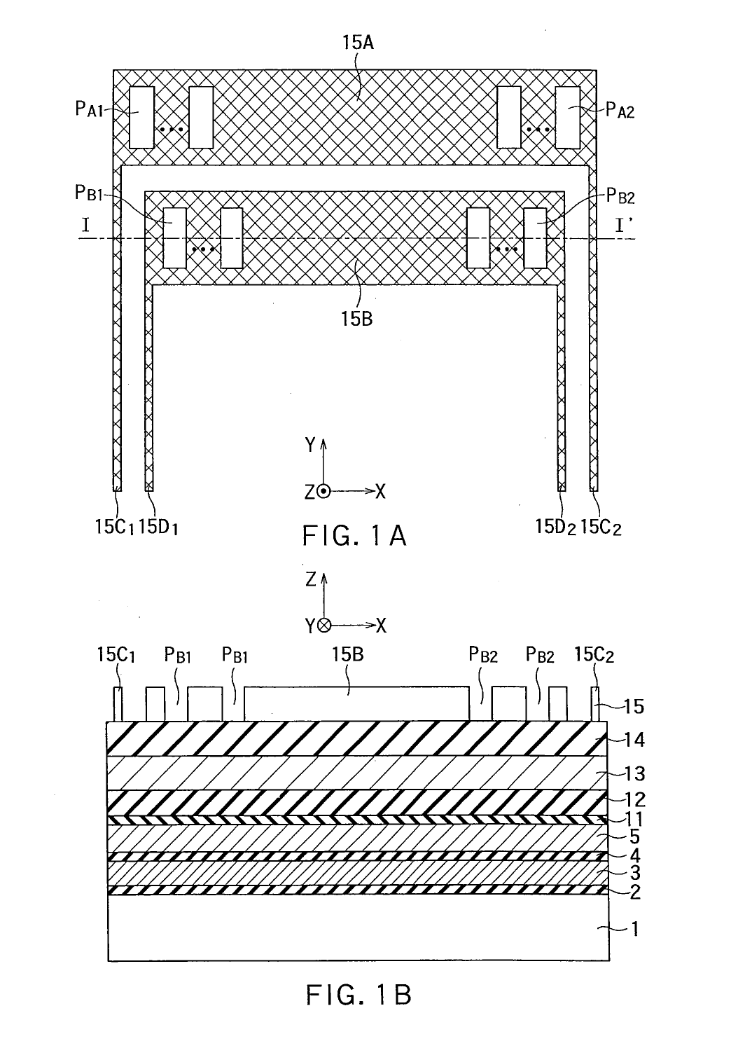

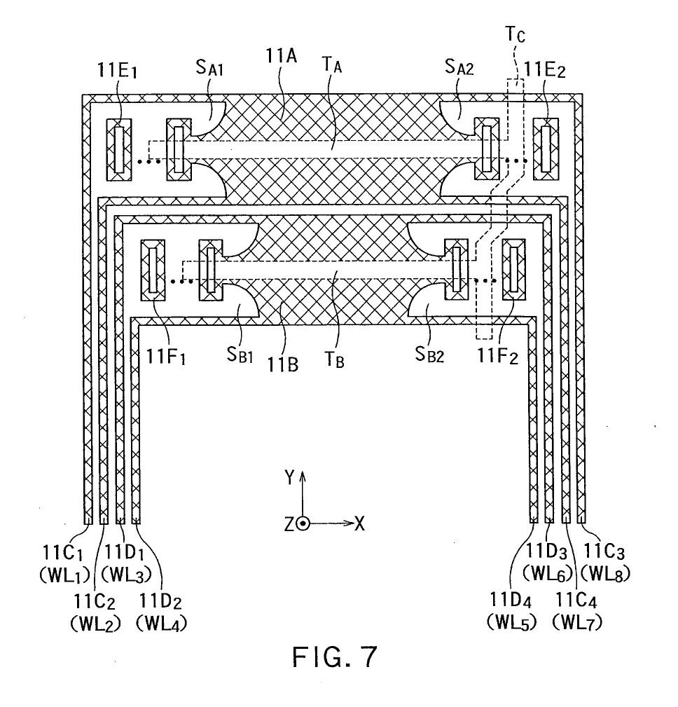

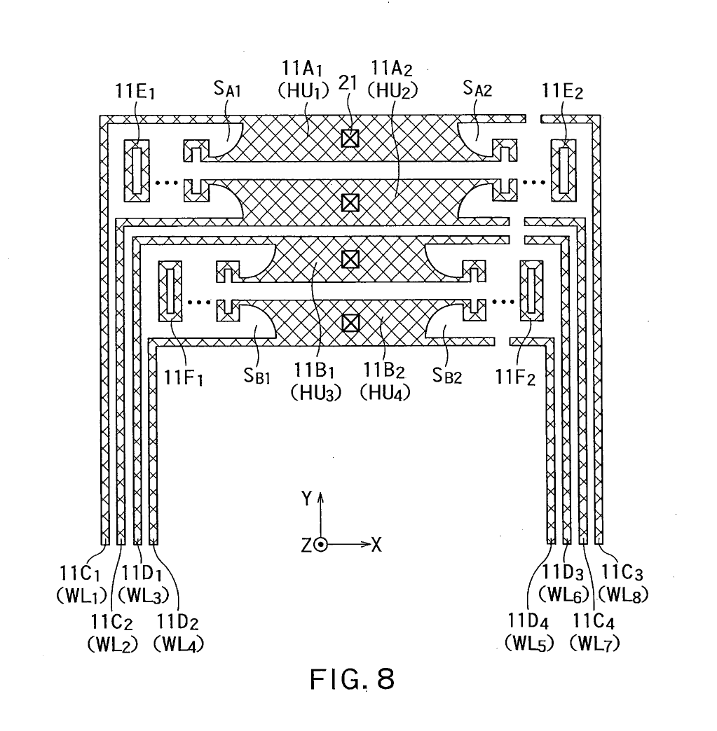

FIGS. 1A to 6B are plan views and cross-sectional views showing a method of manufacturing a semiconductor device of a first embodiment. FIGS. 7 and 8 are plan views showing the method of manufacturing the semiconductor device of the first embodiment. The semiconductor device of the present embodiment is a NAND memory.

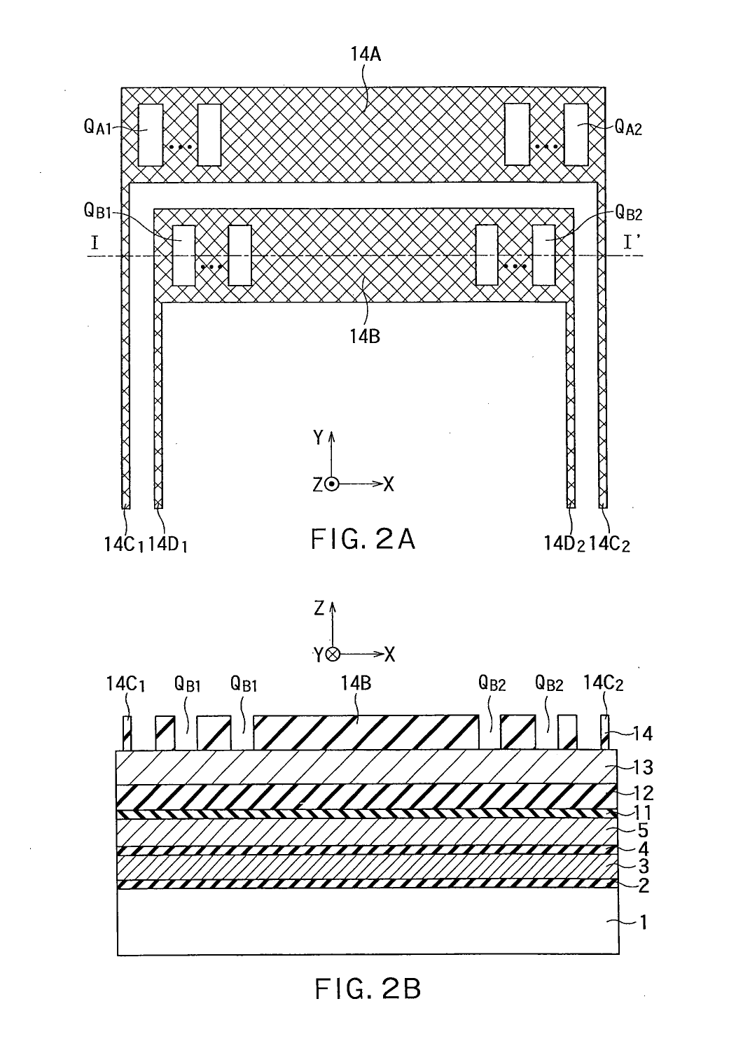

FIG. 1A is a plan view showing the semiconductor device of the present embodiment. FIG. 1B is a cross-sectional view taken along line I-I′ in FIG. 1A. The same goes for FIGS. 2A to 8B.

[FIGS. 1A and 1B]

First, a gate insulator 2, a. floating gate material 3, an inter gate insulator 4, a control gate material 5 that is an example of the interconnect layer, a first mask layer 11, a second mask layer 12, a hard mask layer 13 that is an example of the first film, a core material 14 that is an example of the second film, and a resist film 15 are formed in order, on a substrate 1 (FIGS. 1A and 1B).

Examples of the substrate 1 include a semiconductor substrate such as a silicon substrate. FIGS. 1A and 1B show an X direction and Y direction that are parallel to the surface of the substrate 1 and that are perpendicular to each other, and show a Z direction that are perpendicular to the surface of the substrate 1. The X direction and the Y direction are examples of the first direction and the second direction, respectively.

In this specification, the +Z direction is handled as the upward direction, and the −Z direction is handled as the downward direction. For example, the positional relation between the substrate 1 and the resist film 15 is described as the substrate 1 being positioned below the resist film 15. The −Z direction in the present embodiment may agree with the gravity direction, or may disagree with the gravity direction.

Examples of the gate insulator 2 include a silicon oxide film. Examples of the floating gate material 3 include a polysilicon layer. Examples of the inter gate insulator 4 include a silicon oxide film, a silicon nitride film, and a laminated film including them. Examples of the control gate material 5 include a polysilicon layer, a metal layer, and a laminated film including them.

Examples of the first mask layer 11 include an insulator such as a silicon nitride film. Examples of the second mask layer 12 include a silicon oxide film. Examples of the hard mask layer 13 include a polysilicon layer and an amorphous silicon layer. Examples of the core material 14 include a silicon oxide film.

Next, the resist film 15 is processed by lithography (FIGS. 1A and 1B). As a result, the resist film 15 is processed into a resist pattern including belt portions 15A, 15B and line portions 15C₁, 15C₂, 15D₁, 15D₂.

The belt portion 15A extends in the X direction, and surrounds one or more opening portions P_{A1} and one or more opening portions P_{A2}. The belt portion 15B extends in the X direction, and surrounds one or more opening portions P_{B1} and one or more opening portions P_{B2}. The line portions 15C₁, 15C₂ extend in the Y direction, and are connected with the belt portion 15A. The line portions 15D₁, 15D₂ extend in the Y direction, and are connected with the belt portion 15B. The opening portions P_{A1}, P_{A2} are positioned near end portions of the line portions 15C₁, 15C₂, respectively. The opening portions P_{B1}, P_{B2} are positioned near end portions of the line portions 15D₁, 15D₂, respectively.

The resist pattern further includes multiple belt portions having the same shape as the belt portions 15A, 15B, and multiple line portions having the same shape as the line portions 15C₁, 15C₂, 15D₁, 15D₂, but the illustration of these is omitted in FIG. 1A and FIG. 1B. The same goes for the other patterns shown in FIG. 2A to FIG. 8B.

[FIGS. 2A and 2B]

Next, by the etching using the resist film 15 as a mask, the core material 14 is processed (FIGS. 2A and 2B). As a result, the core material 14 is processed into a core material pattern including belt portions 14A, 14B and line portions 14C₁, 14C₂, 14D₁, 14D₂. The core material pattern is an example of the first pattern. Further, examples of the above etching include a reactive ion etching (RIE).

The belt portion 14A extends in the X direction, and surrounds one or more opening portions Q_{A1} and one or more opening portions Q_{A2}. The belt portion 14B extends in the X direction, and surrounds one or more opening portions Q_{B1} and one or more opening portions Q_{B2}. The line portions 14C₁, 14C₂ extend in the Y direction, and are connected with the belt portion 14A. The line portions 14D₁, 14D₂ extend in the Y direction, and are connected with the belt portion 14B. The opening portions Q_{A1}, Q_{A2} are positioned near end portions of the line portions 14C₁, 14C₂, respectively. The opening portions Q_{B1}, Q_{B2} are positioned near end portions of the line portions 14D₁, 14D₂, respectively.

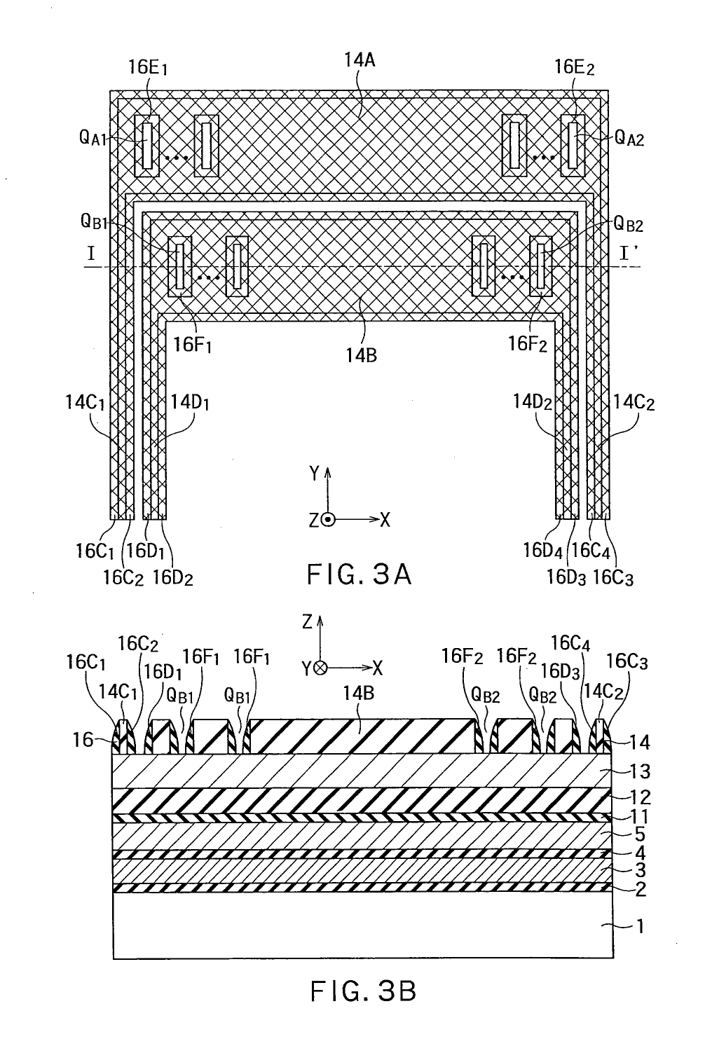

The belt portion 14A, the line portions 14C₁, 14C₂ and the opening portions Q_{A1}, Q_{A2} are examples of the first belt portion, the first and second line portions and the first and second opening portions, respectively. Similarly, the belt portion 14B, the line portions 14D₁, 14D₂ and the opening portions Q_{B1}, Q_{B2} are examples of the first belt portion, the first and second line portions and the first and second opening portions, respectively.

[FIGS. 3A and 3B]

Next, a first sidewall film 16 is formed on the side faces of the core material 14 (FIGS. 3A and 3B). Examples of the first sidewall film 16 include a silicon nitride film.

The first sidewall film 16 includes line portions 16C₁, 16C₂ formed on the side faces of the belt portion 14A and the line portion 14C₁, line portions 16C₃, 16C₄ formed on the side faces of the belt portion 14A and the line portion 14C₂, line portions 16D₁, 16D₂ formed on the side faces of the belt portion 14B and the line portion 14D₁, and line portions 16D₃, 16D₄ formed on the side faces of the belt portion 14B and the line portion 14D₂.

The first sidewall film 16 further includes dummy portions 16E₁, 16E₂ formed on the side faces of the opening portions Q_{A1}, Q_{A2} respectively, and dummy portions 16F₁, 16F₂ formed on the side faces of the opening portions Q_{B1}, Q_{B2} respectively. The dummy portions 16E₁, 16E₂, 16F₁, 16F₂ have a ring shape.

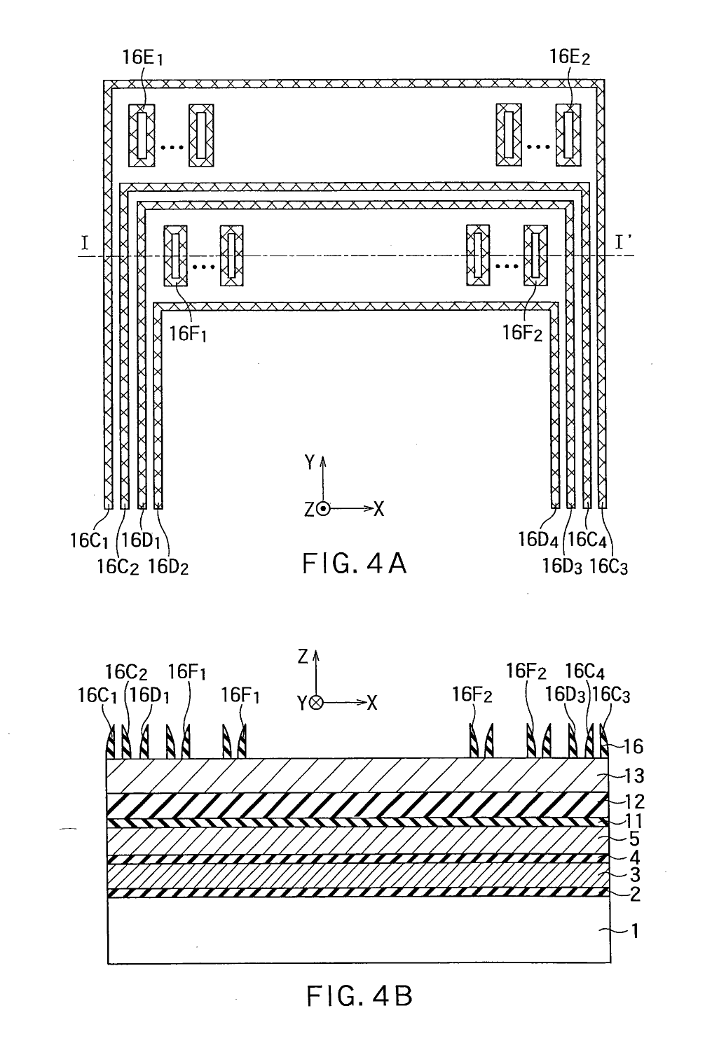

On the side faces of the belt portion 14A, the line portions 16C₁, 16C₂ are connected with the line portions 16C₃, 16C₄, respectively. Further, on the side faces of the belt portion 14B, the line portions 16D₁, 16D₂ are connected with the line portions 16D₃, 16D₄, respectively.

[FIGS. 4A and 4B]

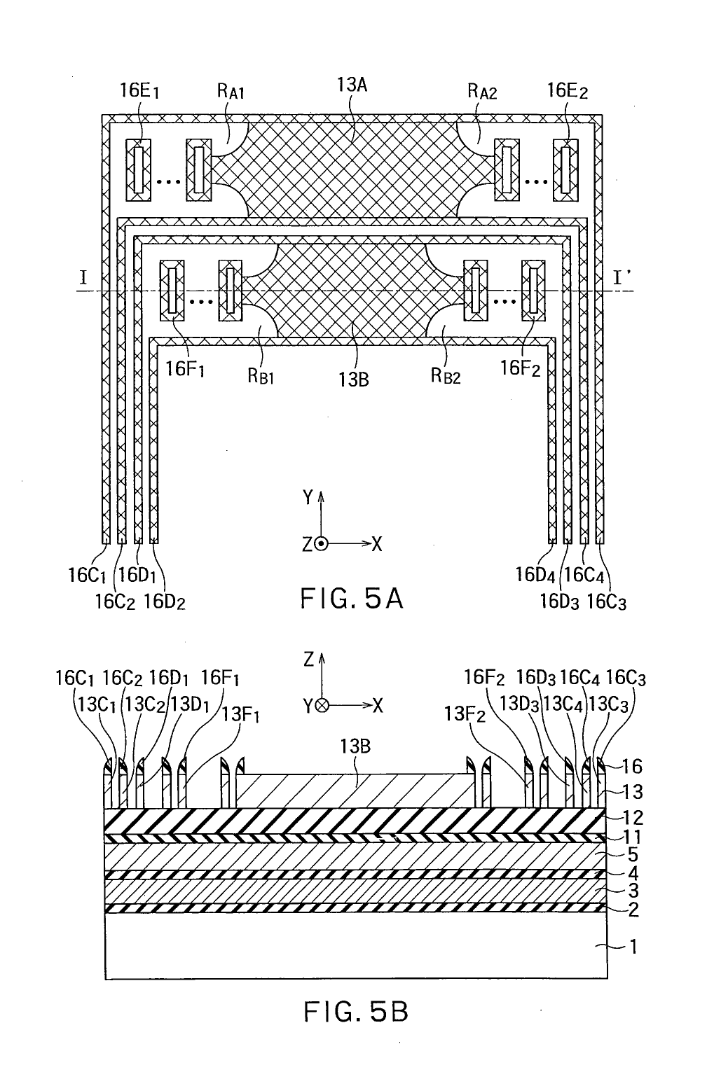

Next, the core material 14 is removed by etching or ashing (FIGS. 4A and 4B).

[FIGS. 5A and 5B]

Next, by the etching using the first sidewall film 16 as a mask, the hard mask layer 13 is processed (FIGS. 5A and 5B). As a result, the hard mask layer 13 is processed into a hard mask pattern including belt portions 13A, 13B, line portions 13C₁ to 13C₄, 13D₁ to 13D₄ and dummy portions 13E₁, 13E₂, 13F₁, 13F₂. The hard mask pattern is an example of the second pattern. Further, examples of the above etching include an RIE. The line portions 13D₂, 13D₄ and the dummy portions 13E₁, 13E₂, for which the illustration is omitted for the convenience of the figure drawing, are positioned under the line portions 16D₂, 16D₄ and the dummy portions 16E₁, 16E₂, respectively.

The belt portions 13A, 13B extend in the X direction. The line portions 13C₁ to 13C₄, 13D₁ to 13D₄ extend mainly in the Y direction. The line portions 13C₁ to 13C₄ are connected with the belt portion 13A, and the line portions 13D₁ to 13D₄ are connected with the belt portion 13B. The dummy portions 13E₁ are positioned between the line portion 13C₁ and the line portion 13C₂, and the dummy portions 13E₂ are positioned between the line portion 13C₃ and the line portion 13C₄. The dummy portions 13F₁ are positioned between the line portion 13D₁ and the line portion 13D₂, and the dummy portions 13F₂ are positioned between the line portion 13D₃ and the line portion 13D₄.

The line portions 16C₁ to 16C₄, 16D₁ to 16D₄ and dummy portions 16E₁, 16E₂, 16F₁, 16F₂ of the first sidewall film 16 are transferred to the hard mask layer 13, and thereby, the line portions 13C₁ to 13C₄, 13D₁ to 13D₄ and dummy portions 13E₁, 13E₂, 13F₁, 13F₂ in the present embodiment are formed.

On the other hand, the belt portions 13A, 13B in the present embodiment are formed by the reverse loading effect. The reverse loading effect accelerates the etching rate for narrow space patterns, and decelerates the etching rate for wide space patterns.

The reason is that the narrow space patterns are largely affected by the etching, compared to the wide space patterns.

In the present embodiment, the space between the line portions 16C₁, 16C₂ and the space between the line portions 16C₃, 16C₄ are wide at a region between the dummy portions 16E₁, 16E₂. Therefore, in the steps of FIGS. 5A and 5B, the hard mask layer 13 at this region remains, and the belt portion 13A is formed. However, the belt portion 13A is formed such that opening portions R_{A1}, R_{A2} remain at corner portions of the belt portion 13A. The reason is that the distances between the line portions 16C₁, 16C₂ and the dummy portions 16E₁ and the distances between the line portions 16C₃, 16C₄ and the dummy portions 16E₂ are short near the corner portions.

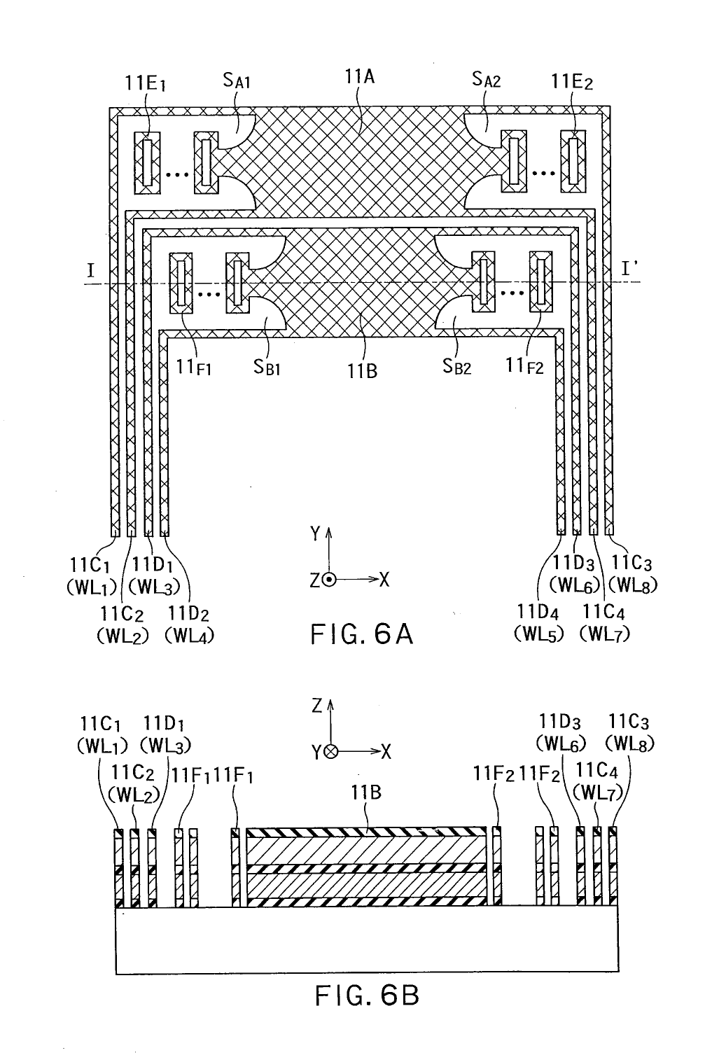

Similarly, the space between the line portions 13D₁, 13D₂ and the space between the line portions 13D₃, 13D₄ are wide at a region between the dummy portions 13F₁, 13F₂. Therefore, in the steps of FIGS. 5A and 5B, the hard mask layer 13 at this region remains, and the belt portion 13B is formed. However, the belt portion 13B is formed such that opening portions R_{B1}, R_{B2} remain at corner portions of the belt portion 13B. The reason is the same as the case of the belt portion 13A.

[FIGS. 6A and 6B]

Next, by the etching using the hard mask layer 13 as a mask, the second mask layer 12, the first mask layer 11, the control gate material 5, the inter gate insulator 4, the floating gate material 3, and the gate insulator 2 are processed (FIGS. 6A and 6B). As a result, the first mask layer 11 is processed into a mask pattern including belt portions 11A, 11B, line portions 11C₁ to 11C₄, 11D₁ to 11D₄ and dummy portions 11E₁, 11E₂, 11F₁, 11F₂. Examples of the above etching include an RIE.

The same goes for the control gate material 5, the inter gate insulator 4, the floating gate material 3, and the gate insulator 2. For example, the control gate material 5 is processed into an interconnect pattern including belt portions 5A, 5B, line portions 5C₁ to 5C₄, 5D₁ to 5D₄, and dummy portions 5E₁, 5E₂, 5F₁, 5F₂.

The belt portions 5A, 5B, the line portions 5C₁ to 5C₄, 5D₁ to 5D₄, and the dummy portions 5E₁, 5E₂, 5F₁, 5F₂, for which the illustration of the reference characters and the shapes is omitted for the convenience of the figure drawing, are positioned under the belt portions 11A, 11B, the line portions 11C₁ to 11C₄, 11D₁ to 11D₄ and the dummy portions 11E₁, 11E₂, 11F₁, 11F₂, respectively. The line portions 5C₁, 5C₂, 5D₁, 5D₂, 5D₄, 5D₃, 5C₄, 5C₃ function as word lines WL₁ to WL₈, respectively.

The belt portions 11A, 11B extend in the X direction. The line portions 11C₁, 11C₂, 11D₁, 11D₂ extend mainly in the Y direction, and are arranged so as to be close to and apart from each other. The line portions 11C₃, 11C₄, 11D₃, 11D₄ extend mainly in the Y direction, and are arranged so as to be close to and apart from each other. The line portions 11C₁ to 11C₄ are connected with the belt portion 11A, and the line portions 11D₁ to 11D₄ are connected with the belt portion 11B. The same goes for the belt portions 5A, 5B, and the line portions 5C₁ to 5C₄, 5D₁ to 5D₄.

The dummy portions 11E₁ are positioned between the line portion 11C₁ and the line portion 11C₂, and are positioned between the belt portion 11A and the line portion 11C₁. The dummy portions 11E₂ are positioned between the line portion 11C₃ and the line portion 11C₄, and are positioned between the belt portion 11A and the line portion 11C₃. The dummy portions 11E₁, 11E₂ have a ring shape. The same goes for the belt portion 5A, the line portions 5C₁ to 5C₄ and the dummy portions 5E₁, 5E₂. The belt portion 5A is an example of the first belt portion. The line portions 5C₁ to 5C₄ are examples of the first to fourth interconnects, respectively. The dummy portions 5E₁, 5E₂ are examples of the one or more fifth interconnects and the one or more sixth interconnects, respectively.

The dummy portions 11F₁ are positioned between the line portion 11D₁ and the line portion 11D₂, and are positioned between the belt portion 11B and the line portion 11D₁. The dummy portions 11F₂ are positioned between the line portion 11D₃ and the line portion 11D₄, and are positioned between the belt portion 11B and the line portion 11D₃. The dummy portions 11F₁, 11F₂ have a ring shape. The same goes for the belt portion 5B, the line portions 5D₁ to 5D₄ and the dummy portions 5F₁, 5F₂. The belt portion 5B is an example of the first belt portion. The line portions 5D₁ to 5D₄ are examples of the first to fourth interconnects, respectively. The dummy portions 5F₁, 5F₂ are examples of the one or more fifth interconnects and the one or more sixth interconnects, respectively.

Similarly to the belt portion 13A, the belt portion 11A in the present embodiment is formed such that opening portions S_{A1}, S_{A2} remain at corner portions of the belt portion 11A. The belt portion 11A is connected with one dummy portion 5E₁, between the opening portions S_{A1}, and is connected with one dummy portion 5E₂, between the opening portions S_{A2}. The same goes for the belt portion 11B and the line portions 11D₁ to 11D₄. Further, the same goes for the belt portions 5A, 5B and the line portions 5C₁ to 5C₄, 5D₁ to 5D₄.

[FIG. 7]

Next, a resist film not shown in the figure is formed on the substrate 1, and the resist film is processed by lithography. As a result, the resist film is processed into a resist pattern including trenches T_{A}, T_{B}, T_{C} for processing (dividing) the belt portions 11A, 11B (FIG. 7).

The trench T_{A} extends in the X direction so as to divide the belt portion 11A into two. The trench T_{A} further extends in the X direction so as to divide the dummy portions 11E₁, 11E₂ connected with the belt portion 11A, into two. The trench T_{B} extends in the X direction so as to divide the belt portion 11B into two. The trench T_{B} further extends in the X direction so as to divide the dummy portions 11F₁, 11F₂ connected with the belt portion 11B, into two. The trench T_{C} extends mainly in the Y direction such that the belt portions 11A, 11B are disconnected from the line portions 11C₃, 11C₄, 11D₃, 11D₄. The trench T_{C} is connected with the trenches T_{A}, T_{B}.

[FIG. 8]

Next, by the etching using the above resist film as a mask, the belt portions 11A, 11B are processed (FIG. 8). The same goes for the control gate material 5, the inter gate insulator 4, the floating gate material 3 and the gate insulator 2. Examples of the above etching include an RIE.

As a result, the belt portion 11A is processed into a belt portion 11A₁ connected with the line portion 11C₁ and separated from the line portion 11C₃, and a belt portion 11A₂ connected with the line portion 11C₂ and separated from the line portion 11C₄. The belt portions 11A₁, 11A₂ extend in the X direction, and are arranged so as to be close to and apart from each other in the Y direction. Each of the dummy portions 11E₁ is positioned between the line portion 11C₁ and the belt portion 11A₁ and/or 11A₂, and each of the dummy portions 11F₁ is positioned between the line portion 11C₃ and the belt portion 11A₁ and/or 11A₂.

Similarly to the belt portion 11A, the belt portion 5A is processed into a belt portion 5A₁ connected with the line portion 5C₁ and separated (electrically insulated) from the line portion 5C₃, and a belt portion 5A₂ connected with the line portion 5C₂ and separated (electrically insulated) from the line portion 5C₄. The belt portions 5A₁, 5A₂ function as pad portions (hook-up portions) HU₁, HU₂ for the word lines WL₁, WL₂, respectively.

The same goes for the belt portion 11B and the belt portion 5B. Similarly to the belt portion 11B, the belt portion 5B is processed into a belt portion 5B₁ connected with the line portion 5D₁ and separated (electrically insulated) from the line portion 5D₃, and a belt portion 5B₂ connected with the line portion 5D₂ and separated (electrically insulated) from the line portion 5D₄. The belt portions 5B₁, 5B₂ function as pad portions HU₃, HU₄ for the word lines WL₃, WL₄, respectively.

Thereafter, in the present embodiment, an inter layer dielectric is formed on the whole surface of the substrate 1, contact holes that penetrate the inter layer dielectric and reach the pad portions HU₁ to HU₄ are formed, and contact plugs 21 are formed on the pad portions HU₁ to HU₄ in the contact holes. Furthermore, various interconnect layers, plug layers, inter layer dielectrics and the like are formed on the substrate 1. In this way, the semiconductor device of the present embodiment is manufactured.

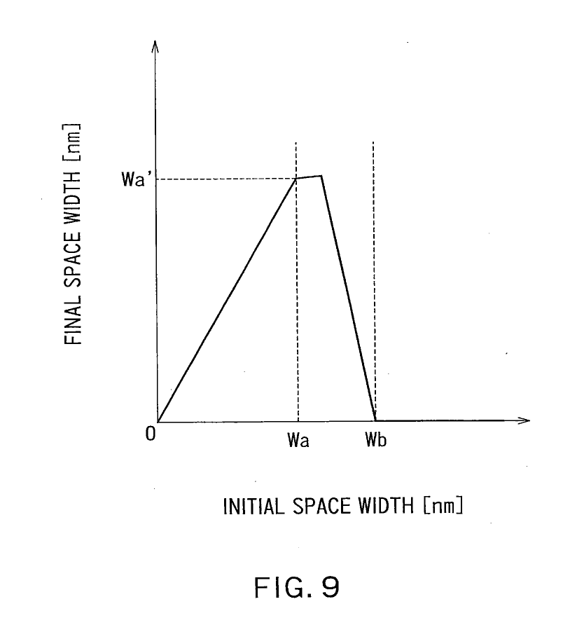

FIG. 9 is a graph showing a relation of an initial space width between patterns of an upper layer and a final space width between patterns of a lower layer, when the patterns of the upper layer are transferred to the lower layer.

In the case where the initial space width is “Wa” or less, the final space width changes so as to be roughly proportional to the initial space width. For example, in the case where the initial space width is “Wa”, the final space width is “Wa”, which is close to “Wa”. Therefore, in the case where the initial space width is “Wa” or less, the shape of the patterns of the lower layer is roughly equal to the shape of the patterns of the upper layer.

However, when the initial space width increases to a range of “Wa” to “Wb”, the change rate of the final space width decreases from a positive value to about 0, and further changes to a negative value. Further, in the case where the initial space width is “Wb” or more, the final space width is 0. Therefore, in the case where the initial space width is “Wb” or more, the patterns of the upper layer are not transferred to the lower layer.

Therefore, in the present embodiment, the space width between the line portions 16C₁, 16C₂, 16D₁, 16D₂ and the space widths between the line portions 16C₃, 16C₄, 16D₃, 16D₄ are set to “Wa” or less. As a result, the patterns of the line portions 16C₁, 16C₂, 16D₁, 16D₂ and the patterns of the line portions 16C₃, 16C₄, 16D₃, 16D₄ are transferred to the hard mask layer 13, as shown in FIGS. 5A and 5B.

Further, in the present embodiment, the space between the line portions 16C₁, 16C₂ and the space between the line portions 16C₃, 16C₄ are set to a width of “Wb” or more, at the region between the dummy portions 16E₁, 16E₂. As a result, the belt portion 13A is formed by the reverse loading effect, as shown in FIGS. 5A and 5B. The same goes for the belt portion 13B.

Further, in the present embodiment, the dummy portions 16E₁ are formed between the line portions 16C₁, 16C₂, and the dummy portions 16E₂ are formed between the line portions 16C₃, 16C₄. As a result, spaces such as the opening portions R_{A1}, R_{A2} remain near the belt portion 13A and the dummy portions 16E₁, 16E₂, as shown in FIG. 5A and FIG. 5B. The same goes for the belt portion 13B.

Therefore, according to the present embodiment, by using these spaces, the trenches T_{A}, T_{B}, T_{C} are easily formed in the belt portions 11A, 11B, and the belt portions 11A, 11B are easily processed.

The trenches T_{A}, T_{B} in the present embodiment, which are formed such that some of the dummy portions 11E₁, 11E₂, 11F₁, 11F₂ are divided, may be formed such that all the dummy portions 11E₁, 11E₂, 11F₁, 11F₂ are divided, or may be formed such that the dummy portions 11E₁, 11E₂, 11F₁, 11F₂ are not divided.

Further, the trench T_{C} in the present embodiment, which is formed at a position deviated from the belt portions 11A, 11B, may be formed in the belt portions 11A, 11B.

In the present embodiment, as shown in FIGS. 2A and 2B, the belt portion 14A is formed so as to surround the opening portions Q_{A1}, Q_{A2}. Therefore, according to the present embodiment, the dummy portions 16E₁, 16E₂ can be formed between the line portions 16C₁, 16C₂, or between the line portions 16C₃, 16C₄, and the spaces such as the opening portions R_{A1}, R_{A2} can remain near the dummy portions 13E₁, 13E₂ (FIGS. 5A and 5B). The same goes for the belt portion 14B.

Therefore, according to the present embodiment, it is possible to form the pad portions HU₁ to HU₄ from the belt portions 5A, 5B, simply and accurately. For example, it is possible to form a wide space in the ±X directions from the belt portions 11A, 11B (5A, 5B), and therefore, it is easy to avoid a mistaken cut of the word lines WL₁ to WL₄ by the trenches T_{A}, T_{B}.

Further, in the present embodiment, it is possible to form the belt portions 5A, 5B and the pad portions HU₁ to HU₄ in a nearly quadrangular shape. Therefore, according to the present embodiment, it is possible to set a wide area for the pad portions HU₁ to HU₄, and to enhance the integration degree of the semiconductor device.

### Modifications of First Embodiment

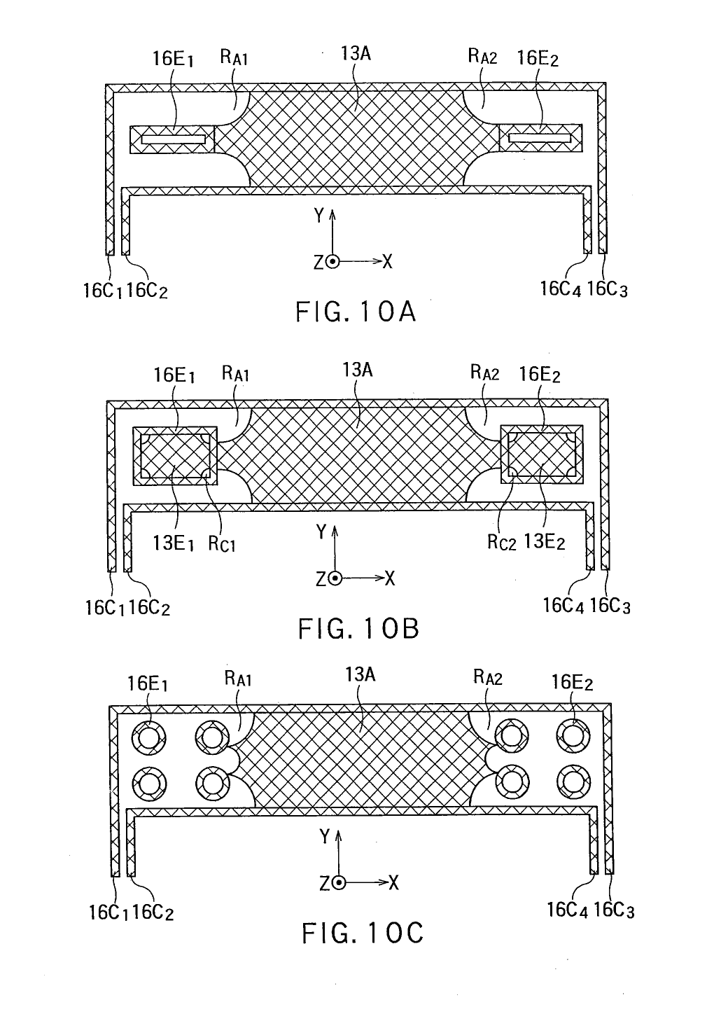

FIGS. 10A to 10C are plan views showing methods of manufacturing semiconductor devices of modifications of the first embodiment. FIGS. 10A to 10C show the same step as FIGS. 5A and 5B.

[FIG. 10A]

The dummy portions 16E₁, 16E₂ in FIG. 5A have a ring shape that extends in the Y direction. Further, in FIG. 5A, the number of the dummy portion 16E₁ and the number of the dummy portion 16E₂ are two or more.

On the other hand, dummy portions 16E₁, 16E₂ in FIG. 10A have a ring shape that extends in the X direction. Further, in FIG. 10A, the number of the dummy portion 16E₁ and the number of the dummy portion 16E₂ are only one.

In this way, it is possible to arbitrarily set the direction in which the dummy portions 16E₁, 16E₂ extend, the number of the dummy portion 16E₁, and the number of the dummy portion 16E₂.

[FIG. 10B]

Dummy portions 16E₁, 16E₂ in FIG. 10B have a ring shape in which the internal area is large. As a result, the hard mask layer 13 under the regions within the dummy portions 16E₁, 16E₂ remains by the reverse loading effect, and the dummy portions 13E₁, 13E₂ have not a ring shape but an island shape.

Dummy portions 13E₁, 13E₂ in FIG. 10B include opening portions R_{C1}, R_{C2} formed by the reverse loading effect, respectively.

[FIG. 10C]

Dummy portions 16E₁, 16E₂ in FIG. 10C have a circular ring shape. In this way, it is possible to set an arbitrary shape, as the shape of the dummy portions 16E₁, 16E₂.

As described above, it is possible to variously set the shape, number and arrangement of the dummy portions 16E₁, 16E₂ in the present embodiment. The same goes for the dummy portions in the other layers.

### Second Embodiment

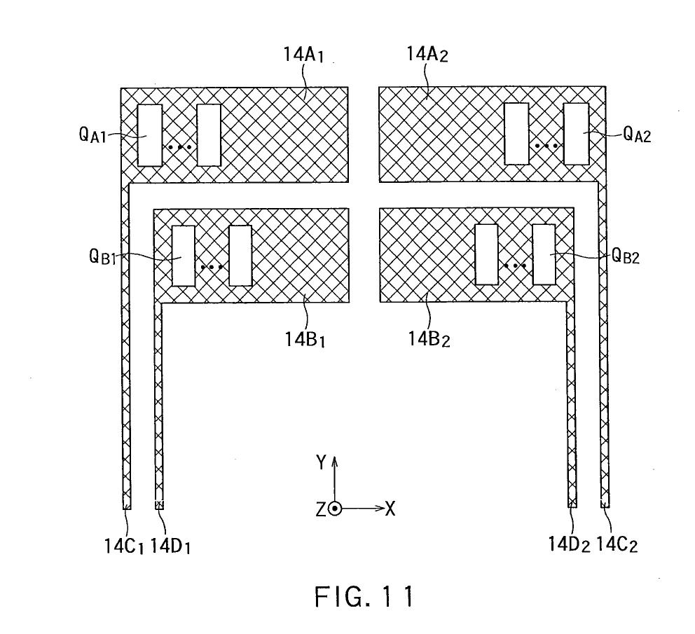

FIGS. 11 to 14 are plan views showing a method of manufacturing a semiconductor device of a second embodiment. In the description of the present embodiment, detailed descriptions for common matters with the first embodiment are omitted.

First, the gate insulator 2, the floating gate material 3, the inter gate insulator 4, the control gate material 5, the first mask layer 11, the second mask layer 12, the hard mask layer 13, the core material 14, and the resist film 15 are formed in order, on the substrate 1, and the resist film 15 is processed by lithography (see FIG. 1B).

[FIG. 11]

Next, by the etching using the resist film 15 as a mask, the core material 14 is processed (FIG. 11). As a result, the core material 14 is processed into a core material pattern including belt portions 14A₁, 14A₂, 14B₁, 14B₂, and line portions 14C₁, 14C₂, 14D₁, 14D₂.

The belt portions 14A₁, 14A₂ extend in the X direction, are arranged so as to be close to and apart from each other in the X direction, and surround one or more opening portions Q_{A1} and one or more opening portions Q_{A2}, respectively. The belt portions 14B₁, 14B₂ extend in the X direction, are arranged so as to be close to and apart from each other in the X direction, and surround one or more opening portions Q_{B1} and one or more opening portions Q_{B2}, respectively. The line portions 14C₁, 14C₂, 14D₁, 14D₂ extend in the Y direction, and are connected with the belt portions 14A₁, 14A₂, 14B₁, 14B₂, respectively. The opening portions Q_{A1}, Q_{A2}, Q_{B1}, Q_{B2} are positioned near end portions of the line portions 14C₁, 14C₂, 14D₁, 14D₂, respectively.

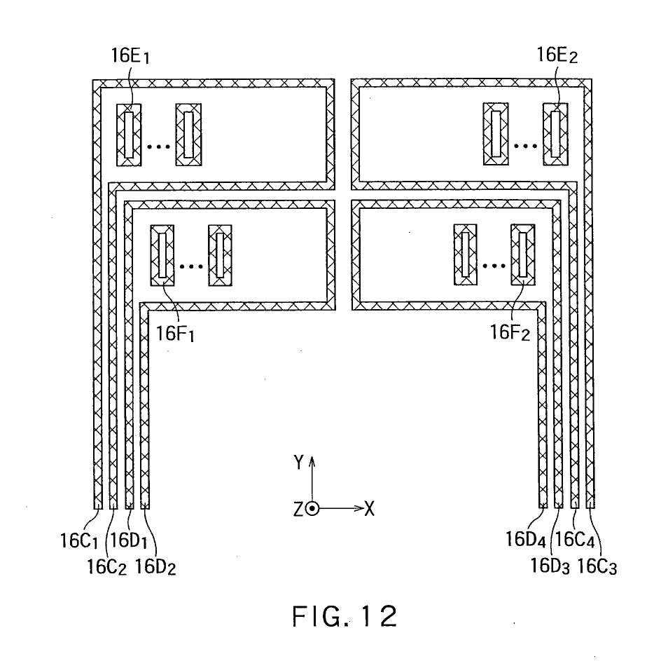

The belt portions 14A₁, 14A₂, the line portions 14C₁, 14C₂, and the opening portions Q_{A1}, Q_{A2} are examples of the first and second belt portions, the first and second line portions, and the first and second opening portions, respectively. Similarly, the belt portions 14B₁, 14B₂, the line portions 14D₁, 14D₂, and the opening portions Q_{B1}, Q_{B2} are examples of the first and second belt portions, the first and second line portions, and the first and second opening portions, respectively.

[FIG. 12]

Next, a first sidewall film 16 is formed on the side faces of the core material 14, and the core material 14 is removed by etching or ashing (FIG. 12).

The first sidewall film 16 includes line portions 16C₁, 16C₂ formed on the side faces of the belt portion 14A₁ and the line portion 14C₁, line portions 16C₃, 16C₄ formed on the side faces of the belt portion 14A₂ and the line portion 14C₂, line portions 16D₁, 16D₂ formed on the side faces of the belt portion 14B₁ and the line portion 14D₁, and line portions 16D₃, 16D₄ formed on the side faces of the belt portion 14B₂ and the line portion 14D₂.

The first sidewall film 16 further includes dummy portions 16E₁, 16E₂ formed on the side faces of the opening portions Q_{A1}, Q_{A2} respectively, and dummy portions 16F₁, 16F₂ formed on the side faces of the opening portions Q_{B1}, Q_{B2} respectively.

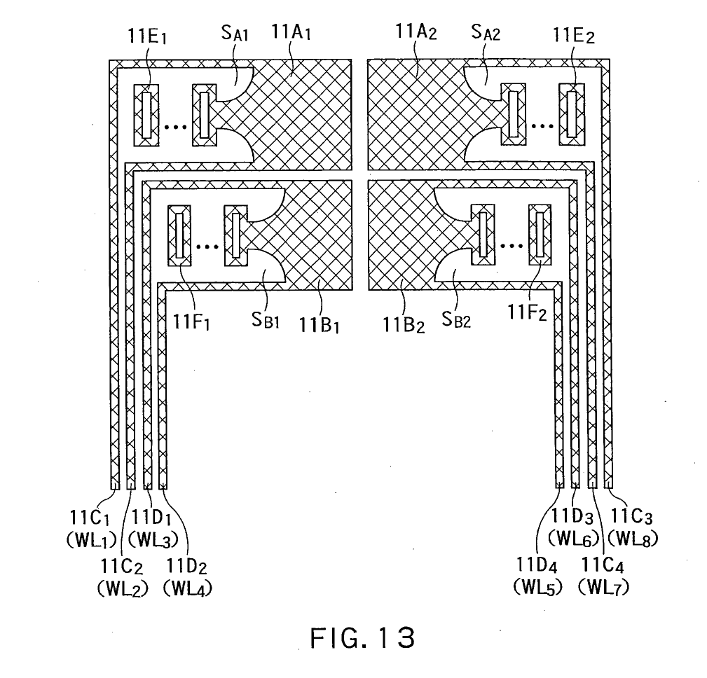

The line portions 16C₁, 16C₂ are connected with each other at the region where the belt portion 14A₁ was present, and the line portions 16C₃, 16C₄ are connected with each other at the region where the belt portion 14A₂ was present. Further, the line portions 16D₁, 16D₂ are connected with each other at the region where the belt portion 14B₁ was present, and the line portions 16D₃, 16D₄ are connected with each other at the region where the belt portion 14B₂ was present.

[FIG. 13]

Next, by the etching using the first sidewall film 16 as a mask, the hard mask layer 13 is processed, and the second mask layer 12, the first mask layer 11, the control gate material 5, the inter gate insulator 4, the floating gate material 3 and the gate insulator 2 are processed by the etching using the hard mask layer 13 as a mask (FIG. 13). As a result, the first mask layer 11 is processed into a mask pattern including belt portions 11A₁, 11A₂, 11B₁, 11B₂, line portions 11C₁ to 11C₄, 11D₁ to 11D₄, and dummy portions 11E₁, 11E₂, 11F₁, 11F₂.

The same goes for the control gate material 5, the inter gate insulator 4, the floating gate material 3, and the gate insulator 2. For example, the control gate material 5 is processed into an interconnect pattern including belt portions 5A₁, 5A₂, 5B₁, 5B₂, line portions 5C₁ to 5C₄, 5D₁ to 5D₄, and dummy portions 5E₁, 5E₂, 5F₁, 5F₂.

The belt portions 5A₁, 5A₂, 5B₁, 5B₂, the line portions 5C₁ to 5C₄, 5D₁ to 5D₄, and the dummy portions 5E₁, 5E₂, 5F₁, 5F₂, for which the illustration of the reference characters and the shapes is omitted for the convenience of the figure drawing, are positioned under the belt portions 11A₁, 11A₂, 11B₁, 11B₂, the line portions 11C₁ to 11C₄, 11D₁ to 11D₄, and the dummy portions 11E₁, 11E₂, 11F₁, 11F₂, respectively. The line portions 5C₁, 5C₂, 5D₁, 5D₂, 5D₄, 5D₃, 5C₄, 5C₃ function as word lines WL₁ to WL₈, respectively.

The line portions 11C₁, 11C₂ are connected with the belt portion 11A₁, and the line portions 11C₃, 11C₄ are connected with the belt portion 11A₂. The belt portions 11A₁, 11A₂ are arranged so as to be close to and apart from each other in the X direction. The line portions 11D₁, 11D₂ are connected with the belt portion 11B₁, and the line portions 11D₃, 11D₄ are connected with the belt portion 11B₂. The belt portions 11B₁, 11B₂ are arranged so as to be close to and apart from each other in the X direction. The same goes for the belt portions 5A₁, 5A₂, 5B₁, 5B₂, and the line portions 5C₁ to 5C₄, 5D₁ to 5D₄.

The dummy portions 11E₁ are positioned between the belt portion 11A₁ and the line portion 11C₁, and the dummy portions 11E₂ are positioned between the belt portion 11A₂ and the line portion 11C₃. The same goes for the belt portions 5A₁, 5A₂, the line portions 5C₁ to 5C₄, and the dummy portions 5E₁, 5E₂. The belt portions 5A₁, 5A₂ are examples of the first and second belt portions. The line portions 5C₁ to 5C₄ are examples of the first to fourth interconnects, respectively. The dummy portions 5E₁, 5E₂ are examples of the one or more fifth interconnects and the one or more sixth interconnects, respectively.

The dummy portions 11F₁ are positioned between the belt portion 11B₁ and the line portion 11D₁, and the dummy portions 11F₂ are positioned between the belt portion 11B₂ and the line portion 11D₃. The same goes for the belt portions 5B₁, 5B₂, the line portions 5D₁ to 5D₄, and the dummy portions 5F₁, 5F₂. The belt portions 5B₁, 5B₂ are examples of the first and second belt portions. The line portions 5D₁ to 5D₄ are examples of the first to fourth interconnects, respectively. The dummy portions 5F₁, 5F₂ are examples of the one or more fifth interconnects and the one or more sixth interconnects, respectively.

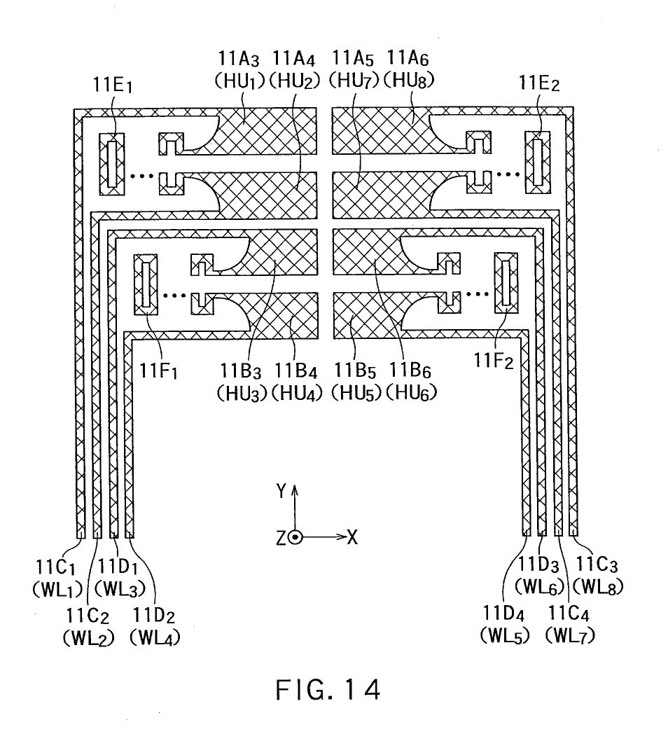

The belt portions 11A₁, 11A₂, 11B₁, 11B₂ in the present embodiment, similarly to the belt portions 11A, 11B in the first embodiment, are formed due to the reverse loading effect when the pattern of the first sidewall film 16 is transferred to the hard mask layer 13.

[FIG. 14]

Next, the belt portions 11A₁, 11A₂, 11B₁, 11B₂ are processed by lithography and etching (FIG. 14). The same goes for the control gate material 5, the inter gate insulator 4, the floating gate material 3, and the gate insulator 2.

As a result, the belt portion 11A₁ is processed into a belt portion 11A₃ connected with the line portion 11C₁ and a belt portion 11A₄ connected with the line portion 11C₂. Further, the belt portion 11A₂ is processed into a belt portion 11A₅ connected with the line portion 11C₄ and a belt portion 11A₆ connected with the line portion 11C₃. The belt portions 11A₃, 11A₄ are arranged so as to be close to and apart from each other in the Y direction, and the belt portions 11A₅, 11A₆ are arranged so as to be close to and apart from each other in the Y direction. Each of the dummy portions 11E₁ is positioned between the line portion 11C₁ and the belt portion 11A₃ and/or 11A₄, and each of the dummy portions 11E₂ is positioned between the line portion 11C₃ and the belt portion 11A₅ and/or 11A₆. The above etching is performed using a resist film that includes the trench T_{A} in FIG. 7.

Similarly to the belt portions 11A₁, 11A₂, the belt portions 5A₁, 5A₂ are processed into belt portions 5A₃, 5A₄, 5A₅, 5A₆ connected with the line portions 5C₁, 5C₂, 5C₄, 5C₃ respectively. The belt portions 5A₃, 5A₄, 5A₅, 5A₆ function as pad portions HU₁, HU₂, HU₇, HU₈ for the word lines WL₁, WL₂, WL₇, WL₈, respectively.

The same goes for the belt portions 11B₁, 11B₂ and the belt portions 5B₁, 5B₂. The belt portions 5B₁, 5B₂ are processed into belt portions 5B₃, 5B₄, 5B₅, 5B₆ connected with the line portions 5D₁, 5D₂, 5D₄, 5D₃ respectively. The belt portions 5B₃, 5B₄, 5B₅, 5B₆ function as pad portions HU₃, HU₄, HU₅, HU₆ for the word lines WL₃, WL₄, WL₅, WL₆, respectively.

Thereafter, in the present embodiment, an inter layer dielectric is formed on the whole surface of the substrate 1, contact holes that penetrate the inter layer dielectric and reach the pad portions HU₁ to HU₄ are formed, and contact plugs 21 are formed on the pad portions HU₁ to HU₄ in the contact holes. Furthermore, various interconnect layers, plug layers, inter layer dielectrics and the like are formed on the substrate 1. In this way, the semiconductor device of the present embodiment is manufactured.

According to the present embodiment, similarly to the first embodiment, it is possible to form the pad portions HU₁ to HU₈ simply and accurately.

The semiconductor device of the first embodiment includes the pad portions HU₁ to HU₄ for the word lines WL₁ to WL₄, within the region shown in FIG. 8, and includes the pad portions HU₅ to HU₈ for the word lines WL₅ to WL₈, in the −Y direction relative to this region. On the other hand, the semiconductor device of the second embodiment includes the pad portions HU₁ to HU₈ for the word lines WL₁ to WL₈, within the region shown in FIG. 14. The first embodiment has an advantage that it is possible to set a wide area for each of the pad portions HU₁ to HU₈, for example. On the other hand, the second embodiment has an advantage that it is possible to collectively arrange the pad portions HU₁ to HU₈ at one place, for example.

### Third Embodiment

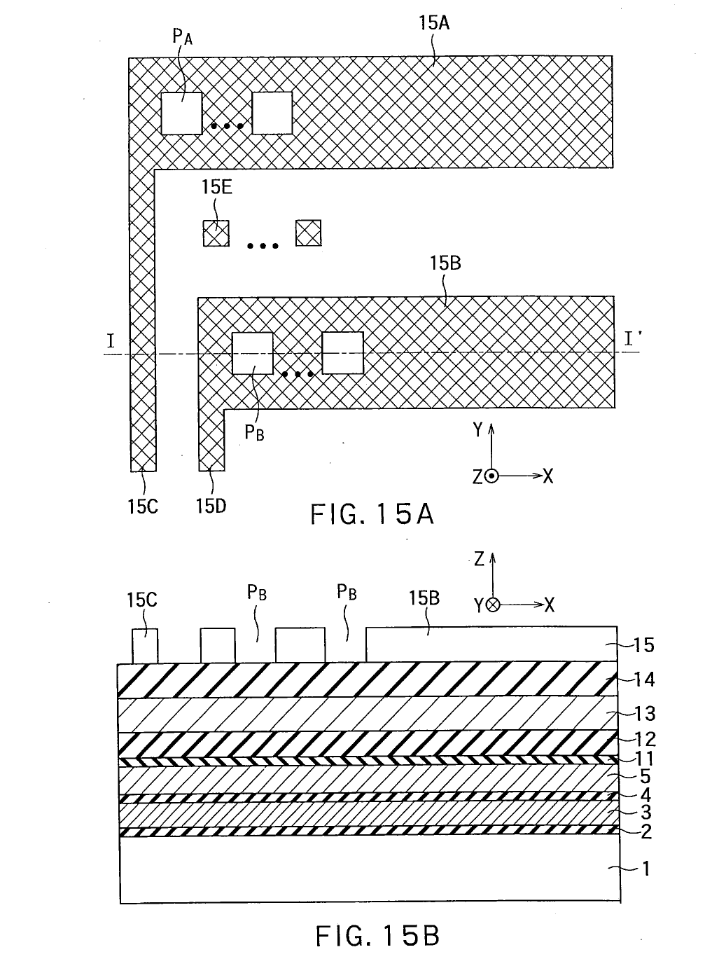

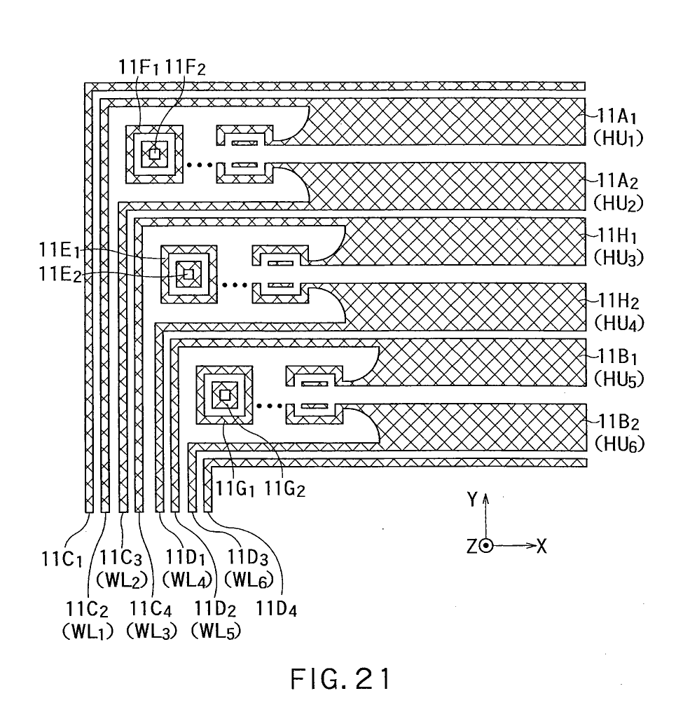

FIGS. 15A to 20B are plan views and cross-sectional views showing a method of manufacturing a semiconductor device of a third embodiment. FIG. 21 is a plan view showing the method of manufacturing the semiconductor device of the third embodiment. In the description of the present embodiment, detailed descriptions for common matters with the first and second embodiments are omitted.

As shown in FIGS. 1A to 6B, the pattern of each layer in the first embodiment has a shape that is bilaterally symmetric (that is symmetric with respect to the Y axis), before the steps of FIG. 7 and FIG. 8. Further, as shown in FIGS. 11 to 14, the pattern of each layer in the second embodiment has a shape that is bilaterally symmetric.

Similarly, the pattern of each layer in the third embodiment has a shape that is bilaterally symmetric, at least before the step of FIG. 21. FIGS. 15A to 21 show the left-half region of the pattern of each layer in the third embodiment.

[FIGS. 15A and 15B]

First, the gate insulator 2, the floating gate material 3, the inter gate insulator 4, the control gate material 5, the first mask layer 11, the second mask layer 12, the hard mask layer 13, the core material 14, and the resist film 15 are formed in order, on the substrate 1 (FIGS. 15A and 15B).

Next, the resist film 15 is processed by lithography (FIGS. 15A and 15B). As a result, the resist film 15 is processed into a resist pattern including belt portions 15A, 15B, line portions 15C, 15D, and one or more dummy portions 15E.

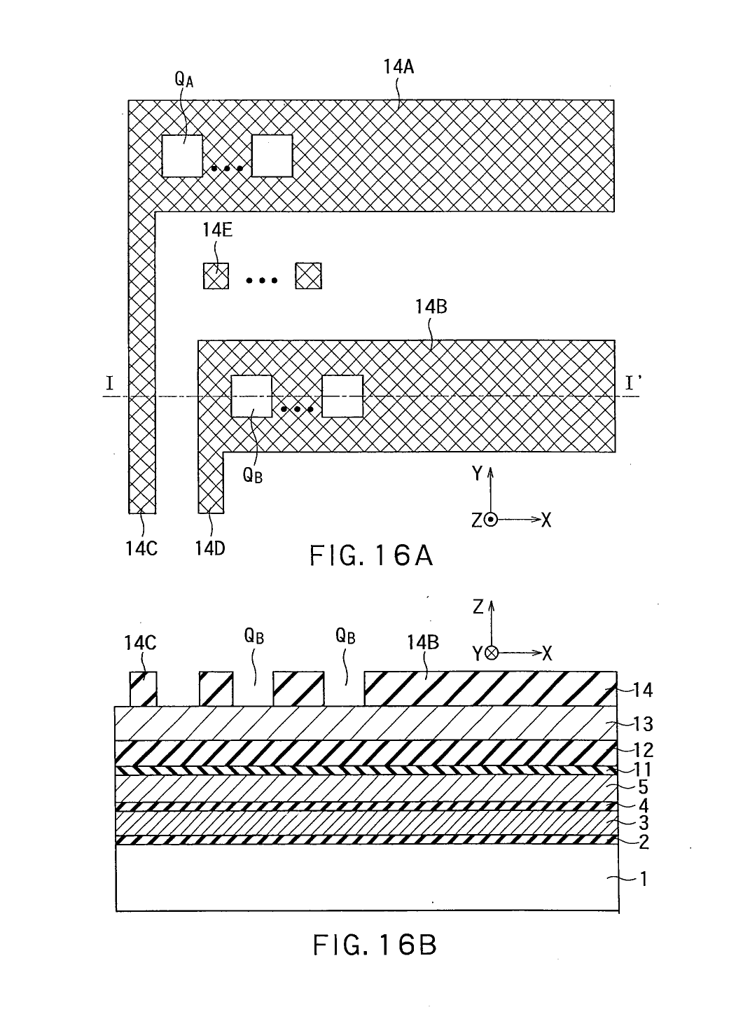

The belt portions 15A, 15B extend in the X direction, and surround one or more opening portions P_{A} and one or more opening portions P_{B}, respectively. The line portions 15C, 15D extend in the Y direction, and are connected with the belt portions 15A, 15B, respectively. The opening portions P_{A}, P_{B} are positioned near ends of the line portions 15C, 15D, respectively. The dummy portions 15E are formed between the belt portion 15A and the belt portion 15B.

[FIGS. 16A and 16B]

Next, by the etching using the resist film 15 as a mask, the core material 14 is processed (FIGS. 16A and 16B). As a result, the core material 14 is processed into a core material pattern including belt portions 14A, 14B, line portion 14C, 14D, and one or more dummy portions 14E.

The belt portions 14A, 14B extend in the X direction, and surround one or more opening portions Q_{A} and one or more opening portions Q_{B}, respectively. The line portions 14C, 14D extend in the Y direction, and are connected with the belt portions 14A, 14B, respectively. The opening portions Q_{A}, Q_{B} are positioned near ends of the line portions 14C, 14D, respectively. The dummy portions 14E are formed between the belt portion 14A and the belt portion 14B. The dummy portions 14E have a point shape.

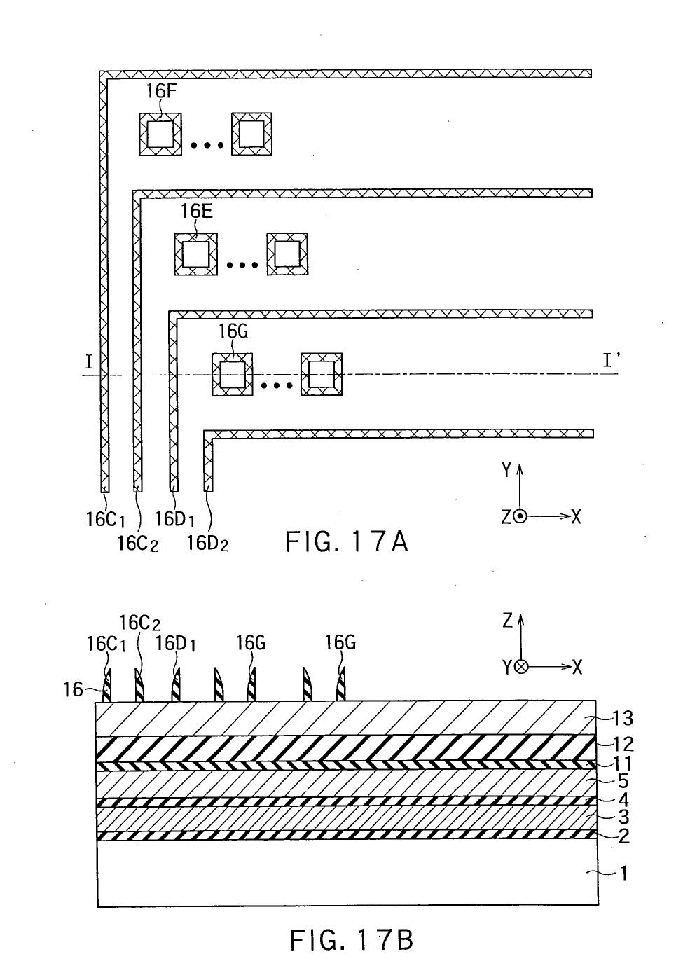

The belt portions 14A, 14B are examples of the first and second belt portions, respectively. The line portion 14C is an example of the first or second line portion. The line portion 14D is an example of the third or fourth line portion. The opening portion Q_{A} is an example of the first or second opening portion. The opening portion Q_{B} is an example of the third or fourth opening portion. The dummy portion 14E is an example of the first or second portion.

[FIGS. 17A and 17B]

Next, a first sidewall film 16 is formed on the side faces of the core material 14, and the core material 14 is removed by etching or ashing (FIGS. 17A and 17B).

The first sidewall film 16 includes line portions 16C₁, 16C₂ formed on the side faces of the belt portion 14A and the line portion 14C, and line portions 16D₁, 16D₂ formed on the side faces of the belt portion 14B and the line portion 14D.

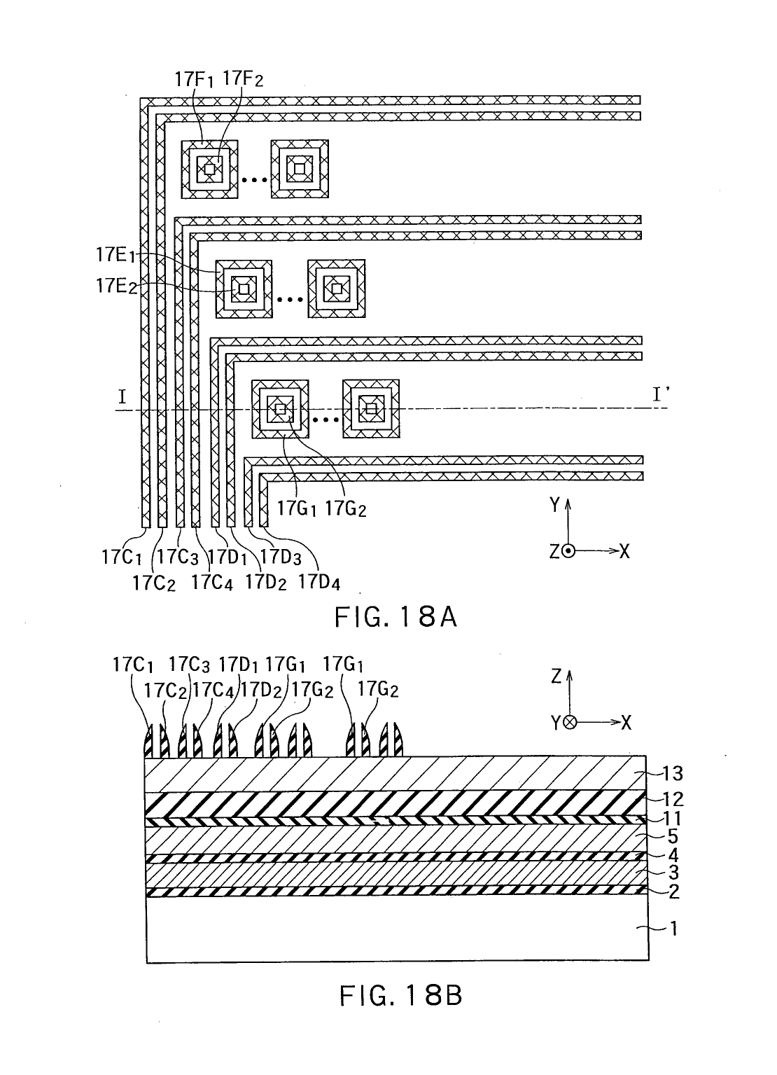

The first sidewall film 16 further includes dummy portions 16E formed on the side faces of the dummy portions 14E, dummy portions 16F formed on the side faces of the opening portions Q_{A}, and dummy portions 16G formed on the side faces of the opening portions Q_{B}. The dummy portions 16E, 16F, 16G have a ring shape.

[FIGS. 18A and 18B]

Next, a second sidewall film 17 is formed on the side faces of the first sidewall film 16, and the first sidewall film 16 is removed by etching or ashing (FIGS. 18A and 18B). Examples of the second sidewall film 17 include a silicon oxide film.

The second sidewall film 17 includes line portions 17C₁, 17C₂ formed on the side faces of the line portion 16C₁, line portions 17C₃, 17C₄ formed on the side faces of the line portion 16C₂, line portions 17D₁, 17D₂ formed on the side faces of the line portion 16D₁, and line portions 17D₃, 17D₄ formed on the side faces of the line portion 16D₂.

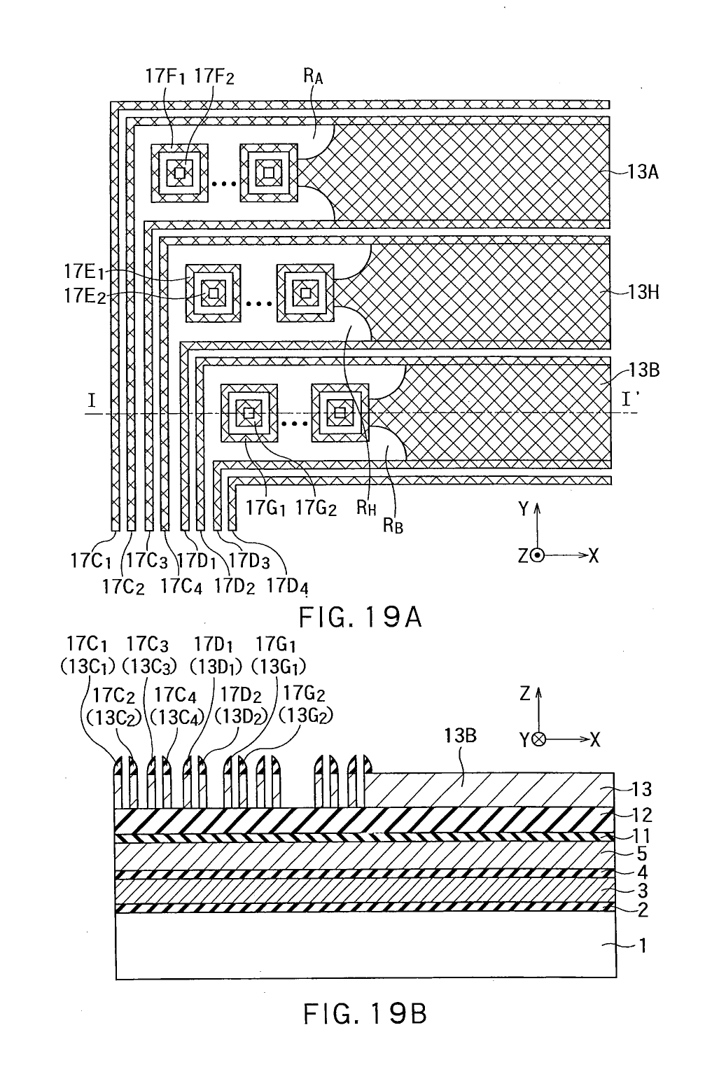

The second sidewall film 17 further includes dummy portions 17E₁, 17E₂ formed on the side faces of the dummy portions 16E, dummy portions 17F₁, 17F₂ formed on the side faces of the dummy portions 16F, and dummy portions 17G₁, 17G₂ formed on the side faces of the dummy portions 16G. The dummy portions 17E₁, 17E₂, 17F₁, 17F₂, 17G₁, 17G₂ have ring shapes.

[FIGS. 19A and 19B]

Next, by the etching using the second sidewall film 17 as a mask, the hard mask layer 13 is processed (FIGS. 19A and 19B). As a result, the hard mask layer 13 is processed into a hard mask pattern including belt portions 13A, 13B, 13H, line portions 13C₁ to 13C₄, 13D₁ to 13D₄, and dummy portions 13E₁, 13E₂, 13F₁, 13F₂, 13G₁, 13G₂. The line portions 13D₃, 13D₄ and the dummy portions 13E₁, 13E₂, 13F₁, 13F₂, for which the illustration is omitted for the convenience of the figure drawing, are positioned under the line portions 17D₃, 17D₄ and the dummy portions 17E₁, 17E₂, 17F₁, 17F₂, respectively.

The belt portions 13A, 13B, 13H extend in the X direction. The line portions 13C₁ to 13C₄, 13D₁ to 13D₄ extend mainly in the Y direction. The line portions 13C₂, 13C₃ are connected with the belt portion 13A, and the dummy portions 13F₁, 13F₂ are positioned between the line portion 13C₂ and the line portions 13C₃.

The line portions 13C₄, 13D₁ are connected with the belt portion 13H, and the dummy portions 13E₁, 13E₂ are positioned between the line portion 13C₄ and the line portion 13D₁. The line portions 13D₂, 13D₃ are connected with the belt portion 13B, and the dummy portions 13G₁, 13G₂ are positioned between the line portion 13D₂ and the line portion 13D₃.

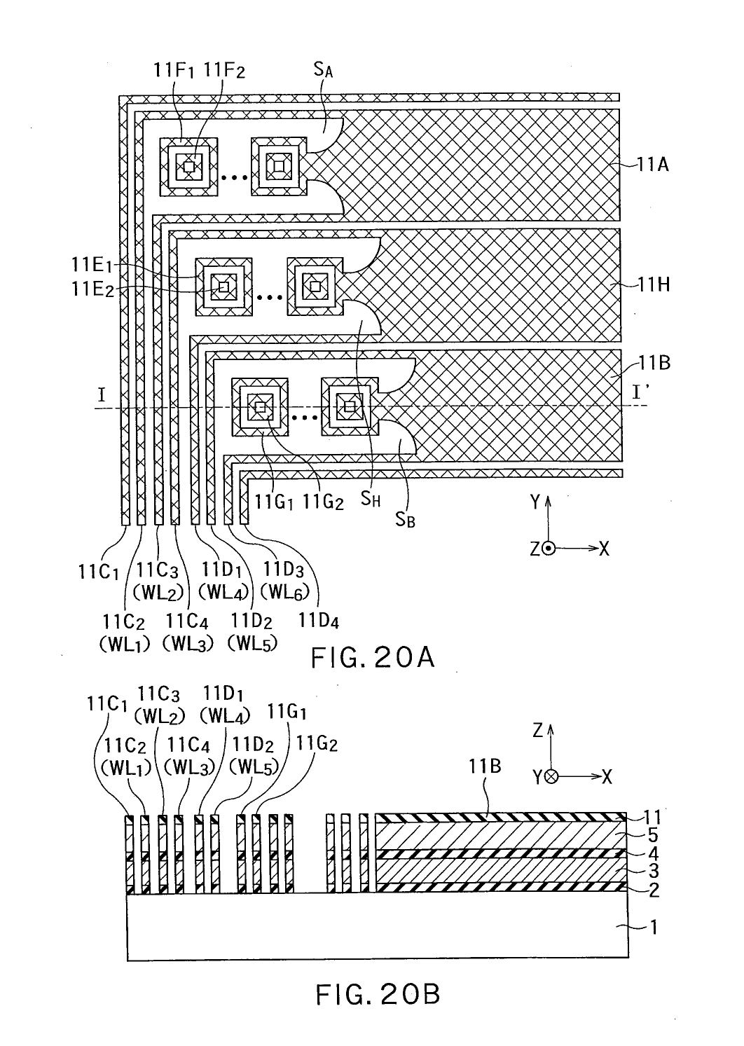

The belt portions 13A, 13B, 13H in the present embodiment are formed by the reverse loading effect. Further, at corner portions of the belt portions 13A, 13B, 13H in the present embodiment, opening portions R_{A}, R_{B}, R_{H} are formed respectively, by the reverse loading effect.

[FIGS. 20A and 20B]

Next, the second mask layer 12, the first mask layer 11, the control gate material 5, the inter gate insulator 4, the floating gate material 3, and the gate insulator 2 are processed by the etching using the hard mask layer 13 as a mask (FIGS. 20A and 20B). As a result, the first mask layer 11 is processed into a mask pattern including belt portions 11A, 11B, 11H, line portions 11C₁ to 11C₄, 11D₁ to 11D₄, and dummy portions 11E₁, 11E₂, 11F₁, 11F₂, 11G₁, 11G₂.

The same goes for the control gate material 5, the inter gate insulator 4, the floating gate material 3 and the gate insulator 2. For example, the control gate material 5 is processed into a line pattern including belt portions 5A, 5B, 5H, line portions 5C₁ to 5C₄, 5D₁ to 5D₄, and dummy portions 5E₁, 5E₂, 5F₁, 5F₂, 5G₁, 5G₂.

The belt portions 5A, 5B, 5H, the line portions 5C₁ to 5C₄, 5D₁ to 5D₄, and the dummy portions 5E₁, 5E₂, 5F₁, 5F₂, 5G₁, 5G₂, for which the illustration of the reference characters and the shapes is omitted for the convenience of the figure drawing, are positioned under the belt portions 11A, 11B, 11H, the line portions 11C₁ to 11C₄, 11D₁ to 11D₄, and the dummy portions 11E₁, 11E₂, 11F₁, 11F₂, 11G₁, 11G₂, respectively. The line portions 5C₂, 5C₃, 5C₄, 5D₁, 5D₂, 5D₃ function as word lines WL₁ to WL₆, respectively.

The belt portions 11A, 11B, 11H extend in the X direction. The line portions 11C₁ to 11C₄, 11D₁ to 11D₄ extend mainly in the Y direction, and are arranged so as to be close to and apart from each other. The line portions 11C₂, 11C₃ are connected with the belt portion 11A, and the dummy portions 11F₁, 11F₂ are positioned between the line portion 11C₂ and the line portion 11C₃. The line portions 11C₄, 11D₁ are connected with the belt portion 11H, and the dummy portions 11E₁, 11E₂ are positioned between the line portion 11C₄ and the line portion 11D₁. The line portions 11D₂, 11D₃ are connected with the belt portion 11B, and the dummy portions 11G₁, 11G₂ are positioned between the line portion 11D₂ and the line portion 11D₃. The dummy portions 11E₁, 11E₂, 11F₁, 11F₂, 11G₁, 11G₂ have ring shapes. The dummy portions 11E₂, 11F₂, 11G₂ are positioned within the dummy portions 11E₁, 11F₁, 11G₁, respectively. At corner portions of the belt portions 13A, 13B, 13H in the present embodiment, opening portions S_{A}, S_{B}, S_{H} are formed respectively.

The same goes for the belt portions 5A, 5B, 5H, the line portions 5C₁ to 5C₄, 5D₁ to 5D₄, and the dummy portions 5E₁, 5E₂, 5F₁, 5F₂, 5G₁, 5G₂. Each of the belt portions 5A, 5B, 5H is an example of the first belt portion. Each of the line portions 5C₂ to 5C₄, 5D₁ to 5D₃ is an example of one of the first to fourth interconnects. Each of the dummy portions 5E₁, 5E₂, 5F₁, 5F₂, 5G₁, 5G₂ is an example of the one or more fifth interconnects or the one or more sixth interconnects.

[FIG. 21]

Next, the belt portions 11A, 11B, 11H are processed by lithography or etching (FIG. 21). The same goes for the control gate material 5, the inter gate insulator 4, the floating gate material 3 and the gate insulator 2.

As a result, the belt portion 11A is processed into a belt portion 11A₁ connected with the line portion 11C₂ and a belt portion 11A₂ connected with the line portion 11C₃. Further, the belt portion 11H is processed into a belt portion 11H₁ connected with the line portion 11C₄ and a belt portion 11H₂ connected with the line portion 11D₁. Further, the belt portion 11B is processed into a belt portion 11B₁ connected with the line portion 11D₂ and a belt portion 11B₂ connected with the line portion 11D₃. The belt portions 11A, 11B, 11H in the present embodiment, similarly to the first embodiment, are disconnected from line portions that are positioned in the +X direction relative to the belt portions 11A, 11B, 11H.

Similarly to the belt portions 11A, 11B, 11H, the belt portions 5A, 5B, 5H are processed into belt portions 5A₁, 5A₂, 5H₁, 5H₂, 5B₁, 5B₂ connected with the line portions 5C₂, 5C₃, 5C₄, 5D₁, 5D₂, 5D₃ respectively. The belt portions 5A₁, 5A₂, 5H₁, 5H₂, 5B₁, 5B₂ function as pad portions HU₁ to HU₆ for the word lines WL₁ to WL₆, respectively.

Thereafter, in the present embodiment, an inter layer dielectric is formed on the whole surface of the substrate 1, contact holes that penetrate the inter layer dielectric and reach the pad portions HU₁ to HU₆ are formed, and contact plugs 21 are formed on the pad portions HU₁ to HU₆ in the contact holes. Furthermore, various interconnect layers, plug layers, inter layer dielectrics and the like are formed on the substrate 1. In this way, the semiconductor device of the present embodiment is manufactured.

According to the present embodiment, similarly to the first embodiment and the second embodiment, it is possible to form the pad portions HU₁ to HU₆ simply and accurately.

The pattern of each layer in the first to third embodiments may have a shape that is bilaterally asymmetric (that is asymmetric with respect to the Y axis).

Further, the first and second sidewall films 16, 17 in the third embodiment may be applied to the method of manufacturing the semiconductor device of the second embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a substrate;
first and second interconnects provided on the substrate so as to be apart from each other;
third and fourth interconnects provided on the substrate so as to be apart from each other;
a first pad portion connected with the first or third interconnect;
a second pad portion connected with the second or fourth interconnect, and provided so as to be apart from the first pad portion;
one or more fifth interconnects including an interconnect provided between the first interconnect and the second interconnect, and provided between at least one of the first and second pad portions and the first interconnect; and
one or more sixth interconnects including an interconnect provided between the third interconnect and the fourth interconnect, and provided between at least one of the first and second pad portions and the third interconnect.

2. The device of claim 1, wherein at least one of the fifth or sixth interconnects includes an interconnect connected with the first or second pad portion.

3. The device of claim 1, wherein at least one of the fifth or sixth interconnects includes an interconnect having a ring shape.

4. The device of claim 3, wherein at least one of the fifth or sixth interconnects includes an interconnect provided in the interconnect having the ring shape.

5. The device of claim 1, wherein
the first pad portion is connected with the first interconnect and is electrically insulated from the third interconnect, and
the second pad portion is connected with the second interconnect and is electrically insulated from the fourth interconnect.

6. The device of claim 1, wherein the first and second pad portions extend in a first direction, and are apart from each other in a second direction perpendicular to the first direction.

7. The device of claim 1, wherein
the first pad portion is connected with the first interconnect,
the second pad portion is connected with the second interconnect, and
the device further comprises:
a third pad portion provided between the first pad portion and the sixth interconnect, and connected with the third interconnect; and
a fourth pad portion provided between the second pad portion and the sixth interconnect, and connected with the fourth interconnect.

8. The device of claim 7, wherein
the third and fourth pad portions are respectively apart from the first and second pad portions in a first direction,
the first and second pad portions are apart from each other in a second direction perpendicular to the first direction, and
the third and fourth pad portions are apart from each other in the second direction.

9. A method of manufacturing a semiconductor device, comprising:
sequentially forming an interconnect layer, a first film and a second film on a substrate;
processing the second film into a first pattern including first and second line portions and a first belt portion which is connected with the first and second line portions and surrounds first and second opening portions;
processing the first film into a second pattern using, as a mask, a first sidewall film formed on a side face of the first pattern or a second sidewall film formed on a side face of the first sidewall film;
processing the interconnect layer, using the second pattern as a mask, into first to fourth interconnects, a first belt portion connected with the first to fourth interconnects, one or more fifth interconnects formed between the first interconnect and the second interconnect, and one or more sixth interconnects formed between the third interconnect and the fourth interconnect; and
processing the first belt portion in the interconnect layer into a first pad portion connected with the first or third interconnect and a second pad portion connected with the second or fourth interconnect.

10. The method of claim 9, wherein
the first pad portion is processed so as to be connected with the first interconnect and to be separated from the third interconnect, and
the second pad portion is processed so as to be connected with the second interconnect and to be separated from the fourth interconnect.

11. The method of claim 9, wherein the first and second pad portions are processed so as to extend in a first direction and to be apart from each other in a second direction perpendicular to the first direction.

12. The method of claim 9, wherein at least one of the fifth or sixth interconnects includes an interconnect having a ring shape.

13. The method of claim 12, wherein at least one of the fifth or sixth interconnects includes an interconnect formed in the interconnect having the ring shape.

14. The method of claim 9, wherein
the fifth interconnect is formed using the first or second sidewall film which is formed using a side face of the first opening portion, and
the sixth interconnect is formed using the first or second sidewall film which is formed using a side face of the second opening portion.

15. The method of claim 9, wherein the first pattern further includes third and fourth line portions, a second belt portion connected with the third and fourth line portions and surrounding third and fourth opening portions, and first and second portions formed between the first belt portion and the second belt portion.

16. The method of claim 13, wherein
the fifth interconnect is formed using the first or second sidewall film which is formed using a side face of the first opening portion or the first portion, and
the sixth interconnect is formed using the first or second sidewall film which is formed using a side face of the second opening portion or the second portion.

17. A method of manufacturing a semiconductor device, comprising:
sequentially forming an interconnect layer, a first film and a second film on a substrate;
processing the second film into a first pattern including first and second line portions, a first belt portion connected with the first line portion and surrounding a first opening portion, and a second belt portion connected with the second line portion, surrounding a second opening portion, and apart from the first belt portion in a first direction;
processing the first film into a second pattern using, as a mask, a first sidewall film formed on a side face of the first pattern or a second sidewall film formed on a side face of the first sidewall film;
processing the interconnect layer, using the second pattern as a mask, into first to fourth interconnects, a first belt portion connected with the first and second interconnects, a second belt portion connected with the third and fourth interconnects and apart from the first belt portion in the first direction, one or more fifth interconnects formed between the first interconnect and the second interconnect, and one or more sixth interconnects formed between the third interconnect and the fourth interconnect;
processing the first belt portion into a first pad portion connected with the first interconnect, and a second pad portion connected with the second interconnect and apart from the first pad portion in a second direction perpendicular to the first direction; and
processing the second belt portion into a third pad portion connected with the third interconnect, and a fourth pad portion connected with the fourth interconnect and apart from the third pad portion in the second direction.

18. The method of claim 17, wherein at least one of the fifth or sixth interconnects includes an interconnect having a ring shape.

19. The method of claim 18, wherein at least one of the fifth or sixth interconnects includes an interconnect formed in the interconnect having the ring shape.

20. The method of claim 17, wherein
the fifth interconnect is formed using the first or second sidewall film which is formed using a side face of the first opening portion, and
the sixth interconnect is formed using the first or second sidewall film which is formed using a side face of the second opening portion.
